(19) United States
(12) Patent Application Publication
(10) Pub. No.: US 2024/0224777 A1
(43) Pub. Date: Jul. 4, 2024

(54) DISPLAY DEVICE

(71) Applicant: LG Display Co., Ltd., Seoul (KR)

(72) Inventors: Gyujae YOHN, Seoul (KR); DongYoon KIM, Seongnam-si (KR)

(73) Assignee: LG Display Co., Ltd., Seoul (KR)

(21) Appl. No.: 18/534,829

(22) Filed: Dec. 11, 2023

(30) Foreign Application Priority Data
Dec. 29, 2022 (KR) 10-2022-0188556

(51) Int. Cl. H10K 77/10

(52) U.S. Cl. CPC H10K 77/111

(57) ABSTRACT

A display device includes a substrate including a display area including a plurality of subpixels, and a non-display area, a film member on a lower portion of the substrate, a bonding layer between the film member and the substrate, and an insulation layer on the substrate, in which the plurality of subpixels each includes a light-emitting area in which a light-emitting element is disposed, and a circuit area in which a drive circuit for operating the light-emitting element is disposed, in which the substrate includes a plurality of first substrate patterns disposed to correspond to the light-emitting area, and a second substrate pattern disposed to correspond to the circuit area, and in which the plurality of first substrate patterns and the second substrate pattern are made of different materials, thereby minimizing parasitic capacitance of the substrate and further improve transmittance of the display device.

### CROSS-REFERENCE TO RELATED APPLICATION

This application claims the priority of Korean Patent Application No. 10-2022-0188556 filed on Dec. 29, 2022, which is hereby incorporated by reference in its entirety.

### BACKGROUND

### Field of the Disclosure

The present disclosure relates to a display device, and more particularly, to a display device that minimizes parasitic capacitance, has improved transmittance, and minimizes the occurrence and propagation of cracks.

### Description of the Background

As display devices used for a monitor of a computer, a TV set, a mobile phone, and the like, there are an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In addition, recently, a flexible display device, which is made by forming display elements, lines, and the like on a substrate made of a flexible plastic material having flexibility and thus may display images even by being folded or rolled up, has attracted attention as a next-generation display device.

### SUMMARY

Accordingly, the present disclosure is directed to a display device that substantially achieves the desires described above.

More specifically, the present disclosure is to provide a display device that uses a substrate made of a silicon material and a transparent conducting oxide material or an oxide semiconductor material instead of a plastic substrate.

The present disclosure is also to provide a display device that minimizes penetration of moisture and oxygen.

The present disclosure is also to provide a display device capable of simplifying a process and reducing manufacturing costs by eliminating a plastic substrate.

The present disclosure is also to provide a display device that may minimize parasitic capacitance and improve transmittance by using a substrate made of a silicon material and a transparent conducting oxide material or an oxide semiconductor material.

The present disclosure is also to provide a display device that suppresses the occurrence and propagation of cracks.

Further, the present disclosure is to provide a display device with improved transmittance.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings. The present disclosure is not limited to the above-mentioned and other features, which are not mentioned above, may be clearly understood by those skilled in the art from the following descriptions.

To achieve these and other advantages and in accordance with the present disclosure, as embodied and broadly described, a display device includes a substrate comprising a display area including a plurality of subpixels, and a non-display area, a film member on a lower portion of the substrate, a bonding layer between the film member and the substrate and an insulation layer on the substrate, wherein the plurality of subpixels each comprises a light-emitting area in which a light-emitting element is disposed, and a circuit area in which a drive circuit for operating the light-emitting element is disposed, wherein the substrate comprises a plurality of first substrate patterns disposed to correspond to the light-emitting area, and a second substrate pattern disposed to correspond to the circuit area, and wherein the plurality of first substrate patterns and the second substrate pattern are made of different materials.

In another aspect of the present disclosure, a display device includes a substrate comprising a light-emitting area, and a circuit area in which a drive circuit for operating a light-emitting element is disposed, the light-emitting element provided on the substrate and in the light-emitting area and an insulation layer on the substrate, wherein the substrate includes a plurality of first substrate patterns configured to overlap with a part of the light-emitting area and a part of the circuit area, a second substrate pattern configured to overlap with the circuit area and made of a material different from a material of the plurality of first substrate patterns and a plurality of third substrate patterns configured to overlap with the circuit area and disposed between the plurality of first substrate patterns and the second substrate pattern, the plurality of third substrate patterns made of a material different from a material of the plurality of first substrate patterns and a material of the second substrate pattern.

Other detailed matters of the exemplary aspects are included in the detailed description and the drawings.

According to the present disclosure, the substrate, which corresponds to the light-emitting area, is made of a transparent conducting oxide material or an oxide semiconductor material, and the substrate, which corresponds to the circuit area, is made of a silicon-based material. Therefore, it is possible to minimize parasitic capacitance between the substrate and the other constituent elements of the display device and improve driving reliability.

According to the present disclosure, it is possible to easily control moisture permeability by using the silicon material and the transparent conducting oxide material or the oxide semiconductor material for the substrate of the display device.

According to the present disclosure, it is possible to improve flexibility of the display device by using the thin-film substrate including the silicon material and the transparent conducting oxide material or the oxide semiconductor material.

According to the present disclosure, the substrate of the display device is made of the silicon material, the material having flexibility or bondability, and the thin-film transparent conducting oxide material or oxide semiconductor material. Therefore, it is possible to reduce stress occurring when the display device is bent or rolled up, thereby reducing cracks in the display device.

According to the present disclosure, the silicon material and the transparent conducting oxide material or oxide semiconductor material may be used for the substrate of the display device, thereby reducing static electricity occurring on the substrate and improving the display quality.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of a display device according to an exemplary aspect of the present disclosure;

FIG. 2 is a schematic cross-sectional view of the display device according to the exemplary aspect of the present disclosure;

FIG. 3 is a circuit diagram of a subpixel of the display device according to the exemplary aspect of the present disclosure;

FIGS. 4A to 4B are enlarged plan views of the display device according to the exemplary aspect of the present disclosure;

FIG. 5 is a cross-sectional view taken along line V-V′ in FIG. 4A;

FIGS. 6A to 6E are cross-sectional views schematically illustrating a method of manufacturing the display device according to the exemplary aspect of the present disclosure;

FIG. 7 is a cross-sectional view of a display device according to another exemplary aspect of the present disclosure; and

FIGS. 8A to 8F are cross-sectional views schematically illustrating a method of manufacturing the display device according to another exemplary aspect of the present disclosure.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various aspects of the present disclosure may be partially or entirely adhered to or combined with each other and may be interlocked and operated in technically various ways, and the aspects may be carried out independently of or in association with each other.

Hereinafter, a display device according to exemplary aspects of the present disclosure will be described in detail with reference to accompanying drawings.

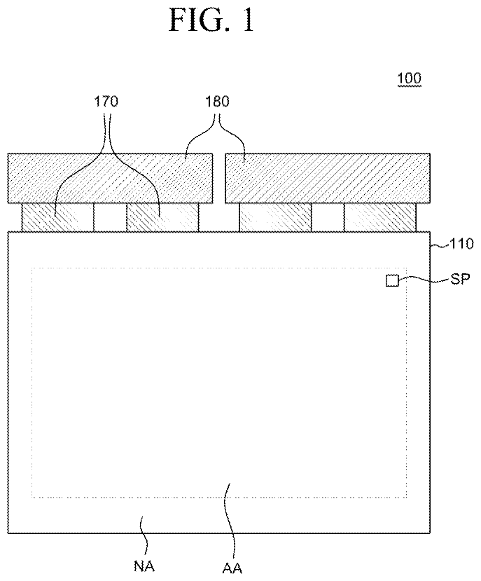

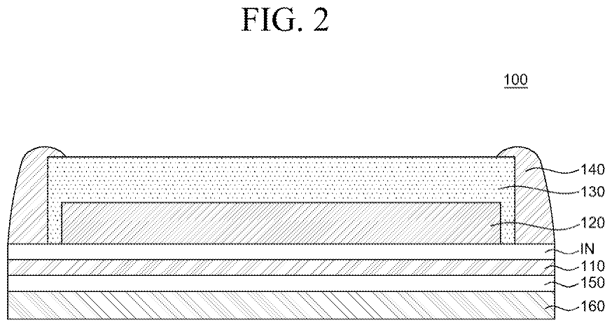

FIG. 1 is a plan view of a display device according to an exemplary aspect of the present disclosure. FIG. 2 is a schematic cross-sectional view of the display device according to the exemplary aspect of the present disclosure. For the convenience of description, FIG. 1 illustrates only a substrate 110, a plurality of flexible films 170, and a plurality of printed circuit boards 180 among various constituent elements of a display device 100.

With reference to FIGS. 1 and 2, the substrate 110 is a support member for supporting the other constituent elements of the display device 100. The substrate 110 may be made of a silicon material and a transparent conducting oxide material or an oxide semiconductor material. More specifically, the transparent conducting oxide material or the oxide semiconductor material may be disposed in an area corresponding to a light-emitting area in which a light-emitting element is disposed. The silicon material may be disposed in an area corresponding to a circuit area in which a drive circuit of a subpixel is disposed.

For example, the transparent conducting oxide material, which constitutes the substrate 110, may be a material such as one or more of indium tin oxide (ITO), indium zinc oxide (IZO), and indium tin zinc oxide (ITZO). For example, the silicon material, which constitutes the substrate 110, may be one or more of hydrogenated amorphous silicon and amorphous silicon hydrogenated and doped with impurities.

In addition, the substrate 110 may be made of an oxide semiconductor material containing indium (In) and gallium (Ga), for example, one or more of a transparent oxide semiconductor such as indium-gallium-zinc oxide (IGZO), indium gallium oxide (IGO), and indium-tin-zinc oxide (ITZO).

However, the materials and types of transparent conducting oxide material and oxide semiconductor materials are exemplarily provided. The substrate 110 may be made of other transparent conducting oxide material and oxide semiconductor material that are not disclosed in the present specification. However, the present disclosure is not limited thereto.

Meanwhile, the substrate 110 may be formed by depositing the transparent conducting oxide or oxide semiconductor with a very small thickness. Therefore, the substrate 110 may have flexibility as the substrate 110 has a very small thickness. Further, the display device 100 including the substrate 110 having flexibility may be implemented as the flexible display device 100 that may display images even though the display device 100 is folded or rolled up. For example, in case that the display device 100 is a foldable display device, the substrate 110 may be folded or unfolded about a folding axis. As another example, in case that the display device 100 is a rollable display device, the display device may be rolled up around a roller and stored. Therefore, the display device 100 according to the exemplary aspect of the present disclosure may be implemented as the flexible display device 100 such as a foldable display device or a rollable display device by using the substrate 110 having flexibility.

In addition, the display device 100 according to the exemplary aspect of the present disclosure may perform a laser-lift-off (LLO) process by using the substrate 110 made of the transparent conducting oxide or oxide semiconductor. The LLO process means a process of separating a temporary substrate, which is disposed below the substrate 110, from the substrate 110 by using a laser during a process of manufacturing the display device 100. Therefore, the substrate 110 is a layer for further facilitating the LLO process, and thus the substrate 110 may be referred to as a functional thin-film, a functional thin-film layer, or a functional substrate. The LLO process will be described below in more detail.

The substrate 110 includes a display area AA and a non-display area NA.

The display area AA is an area in which images are displayed. To display the image, a pixel part 120 including a plurality of subpixels may be disposed in the display area AA. For example, the pixel part 120 includes the plurality of subpixels each including a light-emitting area in which a light-emitting element is disposed, and a circuit area in which a drive circuit is disposed. The pixel part 120 may display images.

The non-display area NA is an area in which no image is displayed. Various lines, drive ICs, and the like for operating the subpixels disposed in the display area AA are disposed. For example, various drive ICs such as a gate driver IC and a data driver IC may be disposed in the non-display area NA.

The plurality of flexible films 170 is disposed at one end of the substrate 110. The plurality of flexible films 170 is electrically connected to one end of the substrate 110. The plurality of flexible films 170 is each a film having various types of components disposed on a base film having flexibility to supply signals to the plurality of subpixels in the display area AA. The plurality of flexible films 170 may each have one end disposed in the non-display area NA of the substrate 110 and supply data voltages or the like to the plurality of subpixels in the display area AA. Meanwhile, FIG. 1 illustrates four flexible films 170. However, the number of flexible films 170 may be variously changed in accordance with design. However, the present disclosure is not limited thereto.

Meanwhile, drive ICs such as gate driver ICs and data driver ICs may be disposed on the plurality of flexible films 170. The drive IC is a component configured to process data for displaying the image and process a driving signal for processing the data. The drive IC may be disposed in ways such as a chip-on-glass (COG) method, a chip-on-film (COF) method, and a tape carrier package (TCP) method depending on how the drive IC is mounted. In the present specification, for the convenience of description, the configuration has been described in which the drive ICs are mounted on the plurality of flexible films 170 by the chip-on-film method. However, the present disclosure is not limited thereto.

The printed circuit boards 180 are connected to the plurality of flexible films 170. The printed circuit board 180 is a component for supplying a signal to the drive IC. Various types of components for supplying the drive IC with various driving signals such as driving signals, data voltages, and the like may be disposed on the printed circuit board 180. Meanwhile, FIG. 1 illustrates two printed circuit boards 180. However, the number of printed circuit boards 180 may be variously changed in accordance with design. The present disclosure is not limited thereto.

With reference to FIG. 2, an insulation layer IN is disposed on the substrate 110. The insulation layer IN may inhibit moisture and/or oxygen penetrating from the outside of the substrate 110 from being diffused. Moisture transmission properties of the display device 100 may be controlled by controlling a thickness or a layered structure of the insulation layer IN. In addition, the insulation layer IN inhibits the substrate 110 made of the transparent conducting oxide or oxide semiconductor from being short-circuited while coming into contact with other components such as the pixel part 120. The insulation layer IN may be made of an inorganic material, for example, configured as a single layer or a multilayer made of silicon oxide (SiOx) or silicon nitride (SiNx). However, the present disclosure is not limited thereto.

The pixel part 120 is disposed on the insulation layer IN. The pixel part 120 may be disposed to correspond to the display area AA. The pixel part 120 includes the plurality of subpixels and is configured to display an image. The plurality of subpixels of the pixel part 120 is minimum units constituting the display area AA. The light-emitting element and the drive circuit may be disposed in each of the plurality of subpixels. For example, the light-emitting element of each of the plurality of subpixels may be an organic light-emitting element including an anode, an organic light-emitting layer, and a cathode or be an LED including N-type and P-type semiconductor layers and a light-emitting layer. However, the present disclosure is not limited thereto. Further, the drive circuit for operating the plurality of subpixels may include driving elements such as a thin-film transistor and a storage capacitor. However, the present disclosure is not limited thereto. Hereinafter, for the convenience of description, the assumption is made that the light-emitting element of each of the plurality of subpixels is the organic light-emitting element. However, the present disclosure is not limited thereto.

Meanwhile, the display device 100 may be a top-emission type display device or a bottom-emission type display device depending on a direction in which light is emitted from the light-emitting element.

The top-emission type display device allows the light emitted from the light-emitting element to propagate toward an upper side of the substrate 110 on which the light-emitting element is disposed. The top-emission type display device may have a reflective layer formed on a lower portion of the anode to allow the light emitted from the light-emitting element to propagate toward the upper side of the substrate 110, i.e., toward the cathode.

The bottom-emission type display device allows the light emitted from the light-emitting element to propagate toward a lower side of the substrate 110 on which the light-emitting element is disposed. In the case of the bottom-emission type display device, the anode may be made of only a transparent electrically conductive material and the cathode may be made of a metallic material with high reflectance to allow the light emitted from the light-emitting element to propagate toward the lower side of the substrate 110.

Hereinafter, for the convenience of description, the display device 100 according to the exemplary aspect of the present disclosure will be described as being the bottom-emission type display device. However, the present disclosure is not limited thereto.

A sealing layer 130 is disposed to cover the pixel part 120. The sealing layer 130 may seal the pixel part 120 and protect the light-emitting element of the pixel part 120 from outside moisture, oxygen, impact, and the like. The sealing layer 130 may be configured as thin-film encapsulation (TFE) in which a plurality of inorganic material layers and a plurality of organic material layers are alternately stacked. For example, the inorganic material layer may be made of an inorganic material such as silicon nitride (SiNx), silicon oxide (SiOx), and aluminum oxide (AlOx). The organic material layer may be made of epoxy-based polymer or acrylic polymer. However, the present disclosure is not limited thereto. In addition, the sealing layer 130 may be configured as a face seal type sealing layer. For example, the sealing layer 130 may be formed by applying an ultraviolet-curable or thermosetting sealant onto the entire surface of the pixel part 120. However, the sealing layer 130 may have various structures and be made of various materials. However, the present disclosure is not limited thereto.

Meanwhile, a sealing substrate may be further disposed on the sealing layer 130. The sealing substrate may be made of a metallic material having a high modulus and high corrosion resistance. For example, the sealing substrate may be made of a material having a modulus as high as about 200 to 900 MPa. The sealing substrate may be made of a metallic material such as aluminum (Al), nickel (Ni), chromium (Cr), iron (Fe), and an alloy of nickel which is easily machined in the form of a foil or thin-film and has high corrosion resistance. Therefore, since the sealing substrate is made of a metallic material, the sealing substrate may be implemented in the form of an ultrathin-film and have protection characteristics strong against outside impact and scratches.

A seal member 140 is disposed to surround side surfaces of the pixel part 120 and the sealing layer 130. The seal member 140 may be disposed in the non-display area NA and disposed to surround the pixel part 120 disposed in the display area AA. The seal member 140 may be disposed to surround the side surface of the pixel part 120 and the side surface of the sealing layer 130, thereby minimizing the penetration of moisture into the pixel part 120. For example, the seal member 140 may be disposed to cover a part of a top surface of the insulation layer IN that overlaps with the non-display area NA protruding to the outside of the pixel part 120. The seal member 140 may be disposed to cover a part of the side surface of the sealing layer 130 disposed to surround the pixel part 120. The seal member 140 may be disposed to cover a part of a top surface of the sealing layer 130.

The seal member 140 may be made of a non-conductive material having elasticity to seal the side surface of the pixel part 120 and increase rigidity of the side surface of the display device 100. In addition, the seal member 140 may be made of a material having bondability. Further, the seal member 140 may further include a moisture absorbent to absorb moisture and oxygen from the outside and minimize the penetration of moisture through a lateral portion of the display device 100. For example, the seal member 140 may be made of a material such as polyimide (PI), polyurethane, epoxy, or acrylic. However, the present disclosure is not limited thereto.

A film member is disposed on a lower portion of the substrate 110. The film member may include at least one of the polarizing plate 160 and a barrier film. For example, the polarizing plate 160 is disposed below the substrate 110. The polarizing plate 160 may selectively transmit light and reduce the reflection of external light entering the substrate 110. Specifically, the display device 100 has various metallic materials formed on the substrate 110 and applied to a semiconductor element, a line, and a light-emitting element. Therefore, the external light entering the substrate 110 may be reflected by the metallic material. The reflection of external light may decrease visibility of the display device 100. In this case, the polarizing plate 160 for suppressing the reflection of external light may be disposed below the substrate 110, thereby improving outdoor visibility of the display device 100. However, the polarizing plate 160 may be excluded in accordance with the implementation of the display device 100.

Meanwhile, a barrier film may be disposed on a lower portion of the substrate 110 together with the polarizing plate 160. Alternatively, the barrier film may be disposed in a state in which the polarizing plate 160 is excluded. The barrier film may minimize the penetration of moisture and oxygen present outside the substrate 110 into the substrate 110, thereby protecting the pixel part 120 including the light-emitting element. However, the barrier film may be excluded in accordance with the implementation of the display device 100. However, the present disclosure is not limited thereto.

A bonding layer 150 is disposed between the film member and the substrate 110. The bonding layer 150 may be made of a material having bondability. The bonding layer 150 may be a thermosetting or naturally curable bonding agent. For example, the bonding layer 150 may be an optical clear adhesive (OCA), a pressure sensitive adhesive (PSA), or the like. However, the present disclosure is not limited thereto.

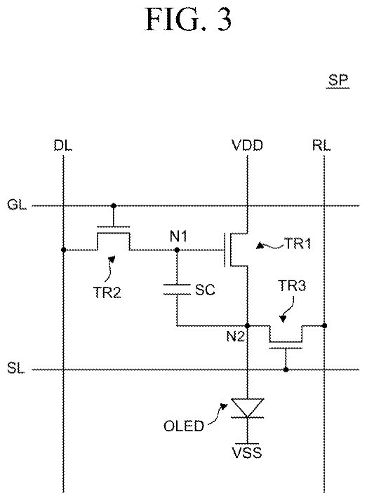

Hereinafter, the plurality of subpixels of the pixel part 120 will be described in more detail with reference to FIGS. 3 to 5.

FIG. 3 is a circuit diagram of the subpixel of the display device according to the exemplary aspect of the present disclosure.

With reference to FIG. 3, a drive circuit for operating a light-emitting element OLED of each of a plurality of subpixels SP includes a first transistor TR1, a second transistor TR2, a third transistor TR3, and a storage capacitor SC. Further, a plurality of lines is disposed on the substrate 110 to operate the drive circuit and includes a gate line GL, a data line DL, a high-potential power line VDD, a sensing line SL, and a reference line RL.

The first transistor TR1, the second transistor TR2, and the third transistor TR3, which are included in the drive circuit of the single subpixel SP, each include a gate electrode, a source electrode, and a drain electrode.

Further, the first transistor TR1, the second transistor TR2, and the third transistor TR3 may each be a P-type thin-film transistor or an N-type thin-film transistor. For example, in the P-type thin-film transistor, positive holes flow from the source electrode to the drain electrode, such that current may flow from the source electrode to the drain electrode. In the N-type thin-film transistor, electrons flow from the source electrode to the drain electrode, such that current may flow from the drain electrode to the source electrode. Hereinafter, the assumption is made that the first transistor TR1, the second transistor TR2, and the third transistor TR3 may each be the N-type thin-film transistor in which current flows from the drain electrode to the source electrode. However, the present disclosure is not limited thereto.

The first transistor TR1 includes a first active layer, a first gate electrode, a first source electrode, and a first drain electrode. The first gate electrode is connected to a first node N1. The first source electrode is connected to the anode of the light-emitting element OLED. The first drain electrode is connected to the high-potential power line VDD. The first transistor TR1 may be turned on when a voltage of the first node N1 is higher than a threshold voltage. The first transistor TR1 may be turned off when the voltage of the first node N1 is lower than the threshold voltage. Further, when the first transistor TR1 is turned on, drive current may be transmitted to the light-emitting element OLED through the first transistor TR1. Therefore, the first transistor TR1 configured to control the drive current to be supplied to the light-emitting element OLED may be referred to as a driving transistor.

The second transistor TR2 includes a second active layer, a second gate electrode, a second source electrode, and a second drain electrode. The second gate electrode is connected to the gate line GL. The second source electrode is connected to the first node N1. The second drain electrode is connected to the data line DL. The second transistor TR2 may be turned on or off on the basis of a gate voltage from the gate line GL. When the second transistor TR2 is turned on, the first node N1 may be charged with the data voltage from the data line DL. Therefore, the second transistor TR2 configured to be turned on or off by the gate line GL may be referred to as a switching transistor.

The third transistor TR3 includes a third active layer, a third gate electrode, a third source electrode, and a third drain electrode. The third gate electrode is connected to the sensing line SL. The third source electrode is connected to a second node N2. The third drain electrode is connected to the reference line RL. The third transistor TR3 may be turned on or off on the basis of a sensing voltage from the sensing line SL. Further, when the third transistor TR3 is turned on, a reference voltage may be transmitted from the reference line RL to the second node N2 and the storage capacitor SC. Therefore, the third transistor TR3 may be referred to as a sensing transistor.

Meanwhile, FIG. 3 illustrates that the gate line GL and the sensing line SL are separate lines. However, the gate line GL and the sensing line SL may be implemented as a single line. However, the present disclosure is not limited thereto.

The storage capacitor SC is connected between the first gate electrode and the first source electrode of the first transistor TR1. That is, the storage capacitor SC may be connected between the first node N1 and the second node N2. The storage capacitor SC may supply a predetermined drive current to the light-emitting element OLED by maintaining a potential difference between the first gate electrode and the first source electrode of the first transistor TR1, such that the light-emitting element OLED emits light. The storage capacitor SC includes a plurality of capacitor electrodes. For example, one of the plurality of capacitor electrodes may be connected to the first node N1, and another capacitor electrode may be connected to the second node N2.

The light-emitting element OLED includes the anode, the light-emitting layer, and the cathode. The anode of the light-emitting element OLED is connected to the second node N2, and the cathode is connected to a low-potential power line VSS. The light-emitting element OLED may emit light by receiving the drive current from the first transistor TR1.

Meanwhile, FIG. 3 illustrates that the drive circuit of the subpixel SP of the display device 100 according to the exemplary aspect of the present disclosure has a 3TIC structure including the three transistors and the single storage capacitor SC. However, the number of transistors, the number of storage capacitors SC, and a connection relationship between the transistor and the storage capacitor may be variously changed in accordance with design. The present disclosure is not limited thereto.

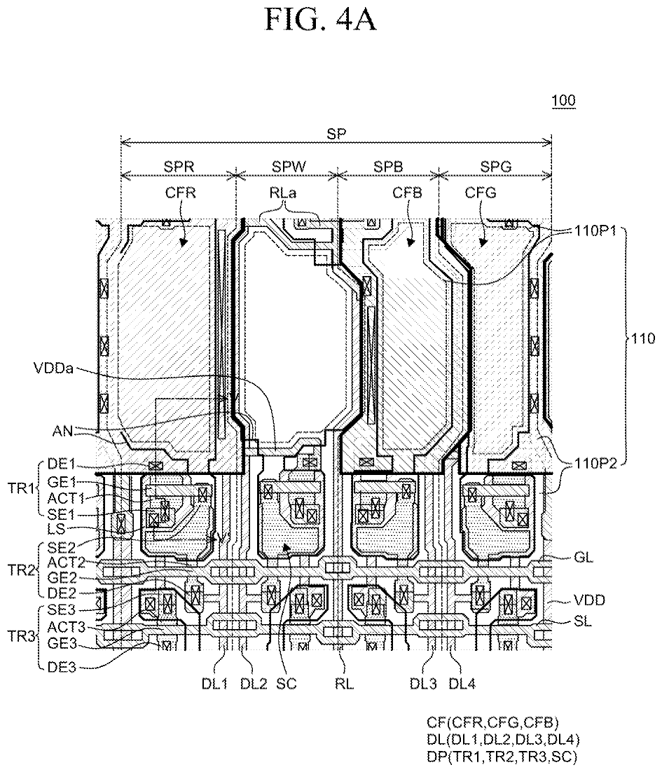

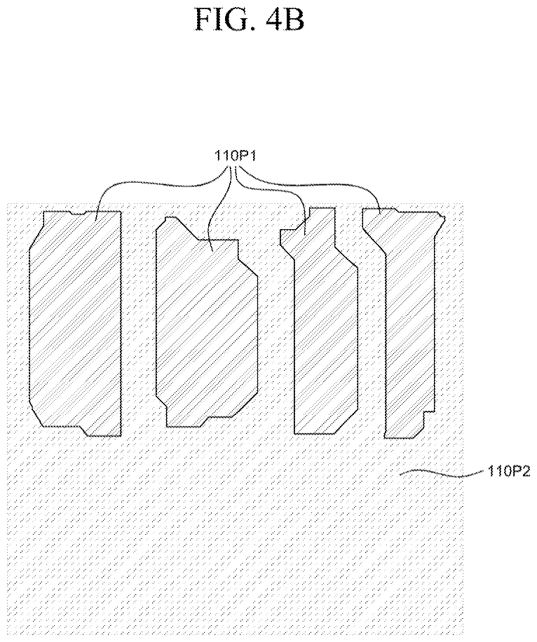

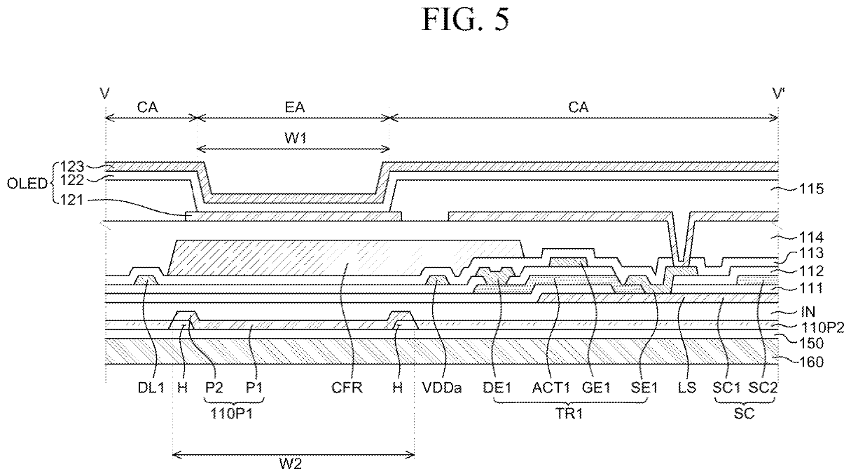

FIGS. 4A to 4B are enlarged plan views of the display device according to the exemplary aspect of the present disclosure. FIG. 5 is a cross-sectional view taken along line V-V′ in FIG. 4A. FIG. 4A is an enlarged plan view of a red subpixel SPR, a white subpixel SPW, a blue subpixel SPB, and a green subpixel SPG that constitute the single pixel. For convenience of description, FIG. 4A does not illustrate a bank 115, and rims of a plurality of color filters CF are indicated by bold solid line. FIG. 4B is an enlarged plan view of the substrate 110 of the display device 100 according to the exemplary aspect of the present disclosure. With reference to FIGS. 4A to 4B and 5, the display device 100 according to the exemplary aspect of the present disclosure includes the substrate 110, the insulation layer IN, a buffer layer 111, a gate insulation layer 112, a passivation layer 113, an overcoating layer 114, the bank 115, the bonding layer 150, the polarizing plate 160, the first transistor TR1, the second transistor TR2, the third transistor TR3, the storage capacitor SC, the light-emitting element OLED, the gate line GL, the sensing line SL, the data line DL, the reference line RL, the high-potential power line VDD, and the plurality of color filters CF.

With reference to FIG. 4A, the plurality of subpixels SP includes the red subpixel SPR, the green subpixel SPG, the blue subpixel SPB, and the white subpixel SPW. For example, the red subpixel SPR, the white subpixel SPW, the blue subpixel SPB, and the green subpixel SPG may be sequentially disposed in a row direction. However, the arrangement order of the plurality of subpixels SP is not limited thereto.

The plurality of subpixels SP each includes a light-emitting area EA and a circuit area CA. The light-emitting area EA is an area that may independently emit light with a single type of color. The light-emitting element OLED may be disposed in the light-emitting area. Specifically, the light-emitting area EA may be defined as an area exposed from the bank 115 and configured such that the light emitted from the light-emitting element OLED may propagate to the outside among the areas in which the plurality of color filters CF and the anode 121 overlap with one another. For example, with reference to FIGS. 4A and 5 together, the light-emitting area EA of the red subpixel SPR may be an area exposed from the bank 115 in an area in which a red color filter CFR and the anode 121 overlap with each other. The light-emitting area EA of the green subpixel SPG may be an area exposed from the bank 115 in an area in which a green color filter CFG and the anode 121 overlap with each other. The light-emitting area EA of the blue subpixel SPB may be a blue light-emitting area that emits blue light in an area exposed from the bank 115 in an area in which a blue color filter CFB and the anode 121 overlap with each other. In this case, the light-emitting area EA of the white subpixel SPW in which no separate color filter CF is disposed may be a white light-emitting area that emits white light in an area that overlaps with a part of the anode 121 exposed from the bank 115.

The circuit area CA is an area except for the light-emitting area EA. A plurality of lines may be disposed in the circuit area and transmit various types of signals to a drive circuit DP for operating the plurality of light-emitting elements OLED. Further, the circuit area CA in which the drive circuit DP, the plurality of lines, and the bank 115 are disposed may be a non-light-emitting area. For example, in the circuit area CA, there may be disposed the drive circuit DP including the first transistor TR1, the second transistor TR2, the third transistor TR3, and the storage capacitor SC, the plurality of high-potential power lines VDD, the plurality of data lines DL, the plurality of reference lines RL, the plurality of gate lines GL, the sensing line SL, and the bank 115.

With reference to FIGS. 3 to 5, the substrate 110 includes a plurality of first substrate patterns 110P1 and a second substrate pattern 110P2.

The plurality of first substrate patterns 110P1 may be disposed to correspond to the light-emitting areas EA. That is, the plurality of first substrate patterns 110P1 may be disposed to overlap with the light-emitting areas EA among the light-emitting areas EA and the circuit area CA. Therefore, as illustrated in FIG. 4B, the plurality of first substrate patterns 110P1 may each have the same shape as each of the light-emitting areas EA. However, the present disclosure is not limited thereto. However, the plurality of first substrate patterns 110P1 may be disposed to correspond to the light-emitting areas EA while each having the same shape as each of the light-emitting areas EA. The plurality of first substrate patterns 110P1 may each have a width W2 larger than a width W1 of the light-emitting area EA. Therefore, some of the plurality of first substrate patterns 110P1 may overlap with a part of the circuit area CA. However, the present disclosure is not limited thereto. The plurality of first substrate patterns 110P1 may each have the same width as each of the light-emitting areas EA and completely overlap with each of the light-emitting areas EA. The plurality of first substrate patterns 110P1 may each be made of a transparent conducting oxide material or an oxide semiconductor.

The plurality of first substrate patterns 110P1 may include a first pattern P1 disposed in a flat area on the substrate 110, and second patterns P2 disposed at two opposite ends of the first pattern P1 and protruding in a direction of the insulation layer IN positioned on the upper portion of the substrate 110, such that the second patterns P2 each have an inclined shape. That is, the second pattern P2 may have a kind of tapered shape. The first pattern P1 may be disposed to overlap with the light-emitting area EA. The second pattern P2 may be disposed to overlap with a partial area of the light-emitting area EA and a partial area of the circuit area CA adjacent to the light-emitting area EA. Therefore, a boundary between the light-emitting area EA and the circuit area CA may overlap with the second pattern P2. However, the present disclosure is not limited thereto. The boundary between the light-emitting area EA and the circuit area CA may be disposed to overlap with the first pattern P1. In general, the transmittance decreases as an incident angle of light increases. Because the plurality of first substrate patterns 110P1 each have an inclined shape, the light introduced in a diagonal direction has the same effect as light introduced from the front surface, which may improve the transmittance of the display device.

The second substrate pattern 110P2 may be disposed to correspond to the circuit area CA. That is, the second substrate pattern 110P2 may be disposed so as not to overlap with the light-emitting element OLED. The second substrate pattern 110P2 may be disposed to only overlap with the plurality of thin-film transistors TR1, TR2, and TR3 configured to operate the light-emitting elements OLED and overlap with the circuit area CA in which the storage capacitor SC and various lines are disposed. The second substrate pattern 110P2 may be made of a silicon-based material. For example, the second substrate pattern 110P2 may be made of the same material as a sacrificial layer used for an LLO process. As described above, the second substrate pattern 110P2, which overlaps with the circuit area CA, is made of a silicon-based material. Therefore, it is possible to suppress the occurrence of parasitic capacitance with the plurality of thin-film transistors TR1, TR2, and TR3, the storage capacitor SC, and various lines disposed in the circuit area CA.

As illustrated in FIG. 4B, the plurality of first substrate patterns 110P1 may be disposed to be surrounded by the second substrate pattern 110P2 in a plan view. In this case, with reference to FIG. 5, a gap H is disposed in a space between each of the first substrate patterns 110P1 and the second substrate pattern 110P2. The gap H may be defined by the plurality of first substrate patterns 110P1, the second substrate pattern 110P2, and the bonding layer 150. That is, the gap H is an area surrounded by the plurality of first substrate patterns 110P1, the second substrate pattern 110P2, and the bonding layer 150. The gap H may be disposed on the bonding layer 150 and overlap with the circuit area CA.

Meanwhile, in the present specification, the configuration has been described in which the substrate 110 includes the plurality of first substrate patterns 110P1 and the second substrate pattern 110P2. The plurality of first substrate patterns 110P1 and the second substrate pattern 110P2 may not be defined on the substrate, but may be defined on other components that perform similar functions to the substrate.

With reference to FIGS. 3 to 5 together, the bonding layer 150 and the polarizing plate 160 are disposed on a lower portion of the substrate 110. The insulation layer IN is disposed on the substrate 110. The plurality of high-potential power lines VDD, the plurality of data lines DL, the plurality of reference lines RL, and a light-blocking layer LS are disposed on the insulation layer IN.

The plurality of high-potential power lines VDD, the plurality of data lines DL, the plurality of reference lines RL, and the light-blocking layer LS may be disposed on the same layer on the substrate 110 and made of the same electrically conductive material. For example, the plurality of high-potential power lines VDD, the plurality of data lines DL, the plurality of reference lines RL, and the light-blocking layer LS may each be made of an electrically conductive material such as copper (Cu), aluminum (Al), molybdenum (Mo), nickel (Ni), titanium (Ti), and chromium (Cr), or an alloy thereof. However, the present disclosure is not limited thereto.

The plurality of high-potential power lines VDD is lines for transmitting high power voltages to the plurality of subpixels SP. The plurality of high-potential power lines VDD may extend in a column direction between the plurality of subpixels SP. The two subpixels SP adjacent to each other in the row direction may share a single high-potential power line VDD among the plurality of high-potential power lines VDD. For example, one high-potential power line VDD may be disposed at the left side of the red subpixel SPR and supply the high-potential power voltage to the first transistor TR1 of each of the red subpixel SPR and the white subpixel SPW. The other high-potential power line VDD may be disposed at the right side of the green subpixel SPG and supply the high-potential power voltage to the first transistor TR1 of each of the blue subpixel SPB and the green subpixel SPG.

The plurality of data lines DL includes a first data line DL1, a second data line DL2, a third data line DL3 and a fourth data line DL4 which are lines that extend in the column direction between the plurality of subpixels SP and transmit the data voltages to the plurality of subpixels SP. The first data line DL1 may be disposed between the red subpixel SPR and the white subpixel SPW and transmit the data voltage to the second transistor TR2 of the red subpixel SPR. The second data line DL2 may be disposed between the first data line DL1 and the white subpixel SPW and transmit the data voltage to the second transistor TR2 of the white subpixel SPW. The third data line DL3 may be disposed between the blue subpixel SPB and the green subpixel SPG and transmit the data voltage to the second transistor TR2 of the blue subpixel SPB. The fourth data line DL4 may be disposed between the third data line DL3 and the green subpixel SPG and transmit the data voltage to the second transistor TR2 of the green subpixel SPG.

The plurality of reference lines RL are lines that extend in the column direction between the plurality of subpixels SP and transmit the reference voltage to the plurality of subpixels SP. The plurality of subpixels SP, which constitute a single pixel, may share the single reference line RL. For example, one reference line RL may be disposed between the white subpixel SPW and the blue subpixel SPB and transmit the reference voltage to the third transistor TR3 of each of the red subpixel SPR, the white subpixel SPW, the blue subpixel SPB, and the green subpixel SPG.

With reference to FIGS. 4A and 5 together, the light-blocking layer LS is disposed on the insulation layer IN. The light-blocking layer LS may be disposed to overlap with a first active layer ACT1 of at least the first transistor TR1 among the plurality of transistors TR1, TR2, and TR3 and inhibit the light from entering the first active layer ACT1. If the light is emitted to the first active layer ACT1, a leakage current occurs, which may degrade the reliability of the first transistor TR1 that is a driving transistor. In this case, when the light-blocking layer LS made of an opaque electrically conductive material such as copper (Cu), aluminum (Al), molybdenum (Mo), nickel (Ni), titanium (Ti), chromium (Cr), or an alloy thereof is disposed to overlap with the first active layer ACT1, the light-blocking layer LS may inhibit the light from entering the first active layer ACT1 from the lower side of the substrate 110, thereby improving the reliability of the first transistor TR1. However, the present disclosure is not limited thereto. The light-blocking layer LS may be disposed to overlap with a second active layer ACT2 of the second transistor TR2 and a third active layer ACT3 of the third transistor TR3.

Meanwhile, the FIG. 5 illustrate that the light-blocking layer LS is a single layer. However, the light-blocking layer LS may be provided as a plurality of layers. For example, the light-blocking layer LS may be provided as a plurality of layers disposed to overlap with one another with at least any one of the insulation layer IN, the buffer layer 111, the gate insulation layer 112, and the passivation layer 113 interposed therebetween.

The buffer layer 111 is disposed on the plurality of high-potential power lines VDD, the plurality of data lines DL, the plurality of reference lines RL, and the light-blocking layer LS. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present disclosure is not limited thereto. In addition, the buffer layer 111 may be eliminated in accordance with the type of substrate 110 or the type of transistor. However, the present disclosure is not limited thereto.

The first transistor TR1, the second transistor TR2, the third transistor TR3, and the storage capacitor SC are disposed on the buffer layer 111 of each of the plurality of subpixels SP.

First, the first transistor TR1 includes the first active layer ACT1, a first gate electrode GE1, a first source electrode SE1, and a first drain electrode DE1.

The first active layer ACT1 is disposed on the buffer layer 111. The first active layer ACT1 may be made of a semiconductor material such as an oxide semiconductor, amorphous silicon, or polysilicon, but the present disclosure is not limited thereto. For example, in the case in which the first active layer ACT1 is made of an oxide semiconductor, the first active layer ACT1 may include a channel area, a source area, and a drain area. The source area and the drain area may be areas having conductivity. However, the present disclosure is not limited thereto.

The gate insulation layer 112 is disposed on the first active layer ACT1. The gate insulation layer 112 may be a layer for insulating the first gate electrode GE1 and the first active layer ACT1 and made of an insulating material. For example, the gate insulation layer 112 may be configured as a single layer or multilayer made of silicon oxide (SiOx) or silicon nitride (SiNx). However, the present disclosure is not limited thereto.

The first gate electrode GE1 is disposed on the gate insulation layer 112 to overlap with the first active layer ACT1. The first gate electrode GE1 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first source electrode SE1 and the first drain electrode DE1 are disposed on the gate insulation layer 112 and spaced apart from each other. The first source electrode SE1 and the first drain electrode DE1 may be electrically connected to the first active layer ACT1 through a contact hole formed in the gate insulation layer 112. The first source electrode SE1 and the first drain electrode DE1 may be disposed on the same layer and made of the same electrically conductive material as the first gate electrode GE1. However, the present disclosure is not limited thereto. For example, the first source electrode SE1 and the first drain electrode DE1 may be made of copper (Cu), aluminum (Al), molybdenum (Mo), nickel (Ni), titanium (Ti), chromium (Cr), or an alloy thereof. However, the present disclosure is not limited thereto.

The first drain electrode DE1 is electrically connected to the high-potential power line VDD. For example, the first drain electrodes DE1 of the red subpixel SPR and the white subpixel SPW may be electrically connected to the high-potential power line VDD at the left side of the red subpixel SPR. The first drain electrodes DE1 of the blue subpixel SPB and the green subpixel SPG may be electrically connected to the high-potential power line VDD at the right side of the green subpixel SPG.

In this case, to electrically connect the first drain electrode DE1 to the high-potential power line VDD, an auxiliary high-potential power line VDDa may be further disposed. The auxiliary high-potential power line VDDa has one end electrically connected to the high-potential power line VDD, and the other end electrically connected to the first drain electrode DE1 of each of the plurality of subpixels SP. For example, in a case in which the auxiliary high-potential power line VDDa is disposed on the same layer and made of the same material as the first drain electrode DE1, one end of the auxiliary high-potential power line VDDa may be electrically connected to the high-potential power line VDD through the contact hole formed in the gate insulation layer 112 and the buffer layer 111, and the other end of the auxiliary high-potential power line VDDa may extend to the first drain electrode DE1 and be integrated with the first drain electrode DE1.

In this case, the first drain electrode DE1 of the red subpixel SPR and the first drain electrode DE1 of the white subpixel SPW, which are electrically connected to the same high-potential power line VDD, may be connected to the same auxiliary high-potential power line VDDa. The first drain electrode DE1 of the blue subpixel SPB and the first drain electrode DE1 of the green subpixel SPG may also be connected to the same auxiliary high-potential power line VDDa. However, the first drain electrode DE1 and the high-potential power line VDD may be electrically connected by means of other methods. However, the present disclosure is not limited thereto.

The first source electrode SE1 may be electrically connected to the light-blocking layer LS through the contact hole formed in the gate insulation layer 112 and the buffer layer 111. In addition, a part of the first active layer ACT1 connected to the first source electrode SE1 may be electrically connected to the light-blocking layer LS through the contact hole formed in the buffer layer 111. If the light-blocking layer LS floats, the threshold voltage of the first transistor TR1 is changed, which may affect the operation of the display device 100. Therefore, the light-blocking layer LS may be electrically connected to the first source electrode SE1, such that the voltage may be applied to the light-blocking layer LS, and the operation of the first transistor TR1 is not affected. In the present specification, the configuration has been described in which both the first active layer ACT1 and the first source electrode SE1 are in contact with the light-blocking layer LS. However, only any one of the first source electrode SE1 and the first active layer ACT1 may be in direct contact with the light-blocking layer LS. The present disclosure is not limited thereto.

Meanwhile, FIG. 5 illustrates that the gate insulation layer 112 is formed on the entire surface of the substrate 110. However, the gate insulation layer 112 may be patterned to overlap with only the first gate electrode GE1, the first source electrode SE1, and the first drain electrode DE1. However, the present disclosure is not limited thereto.

The second transistor TR2 includes the second active layer ACT2, the second gate electrode GE2, a second source electrode SE2, and a second drain electrode DE2.

The second active layer ACT2 is disposed on the buffer layer 111. The second active layer ACT2 may be made of a semiconductor material such as an oxide semiconductor, amorphous silicon, or polysilicon, but the present disclosure is not limited thereto. For example, in the case in which the second active layer ACT2 is made of an oxide semiconductor, the second active layer ACT2 may include a channel area, a source area, and a drain area. The source area and the drain area may be areas having conductivity. However, the present disclosure is not limited thereto.

The second source electrode SE2 is disposed on the buffer layer 111. The second source electrode SE2 may be integrated with and electrically connected to the second active layer ACT2. For example, the second source electrode SE2 may be formed by forming a semiconductor material on the buffer layer 111 and making a part of the semiconductor material conductive. Therefore, a portion of the semiconductor material, which does not become conductive, may be the second active layer ACT2. A portion of the semiconductor material, which becomes conductive, may be the second source electrode SE2. However, the second active layer ACT2 and the second source electrode SE2 may be separately formed. However, the present disclosure is not limited thereto.

The second source electrode SE2 is electrically connected to the first gate electrode GE1 of the first transistor TR1. The first gate electrode GE1 may be electrically connected to the second source electrode SE2 through the contact hole formed in the gate insulation layer 112. Therefore, the first transistor TR1 may be turned on or off in response to a signal from the second transistor TR2.

The gate insulation layer 112 is disposed on the second active layer ACT2 and the second source electrode SE2. The second drain electrode DE2 and the second gate electrode GE2 are disposed on the gate insulation layer 112.

The second gate electrode GE2 is disposed on the gate insulation layer 112 to overlap with the second active layer ACT2. The second gate electrode GE2 may be electrically connected to the gate line GL. The second transistor TR2 may be turned on or off on the basis of the gate voltage transmitted to the second gate electrode GE2. The second gate electrode GE2 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Meanwhile, the second gate electrode GE2 may extend from the gate line GL. That is, the second gate electrode GE2 may be integrated with the gate line GL. The second gate electrode GE2 and the gate line GL may be made of the same electrically conductive material. For example, the gate line GL may be made of copper (Cu), aluminum (Al), molybdenum (Mo), nickel (Ni), titanium (Ti), chromium (Cr), or an alloy thereof. However, the present disclosure is not limited thereto.

The gate line GL is a line for transmitting the gate voltages to the plurality of subpixels SP. The gate line GL may extend in the row direction while traversing a circuit area of the plurality of subpixels SP. The gate line GL may extend in the row direction and intersect the plurality of high-potential power lines VDD, the plurality of data lines DL, and the plurality of reference lines RL that extend in the column direction.

The second drain electrode DE2 is disposed on the gate insulation layer 112. The second drain electrode DE2 may be electrically connected to the second active layer ACT2 through the contact hole formed in the gate insulation layer 112. The second drain electrode DE2 may be electrically connected to one of the plurality of data lines DL through the contact hole formed in the gate insulation layer 112 and the buffer layer 111. For example, the second drain electrode DE2 of the red subpixel SPR may be electrically connected to the first data line DL1. The second drain electrode DE2 of the white subpixel SPW may be electrically connected to the second data line DL2. For example, the second drain electrode DE2 of the blue subpixel SPB may be electrically connected to the third data line DL3. The second drain electrode DE2 of the green subpixel SPG may be electrically connected to the fourth data line DLA. The second drain electrode DE2 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The third transistor TR3 includes a third active layer ACT3, a third gate electrode GE3, a third source electrode SE3, and the third drain electrode DE3.

The third active layer ACT3 is disposed on the buffer layer 111. The third active layer ACT3 may be made of a semiconductor material such as an oxide semiconductor, amorphous silicon, or polysilicon, but the present disclosure is not limited thereto. For example, in the case in which the third active layer ACT3 is made of an oxide semiconductor, the third active layer ACT3 may include a channel area, a source area, and a drain area. The source area and the drain area may be areas having conductivity. However, the present disclosure is not limited thereto.

The gate insulation layer 112 is disposed on the third active layer ACT3. The third gate electrode GE3, the third source electrode SE3, and the third drain electrode DE3 are disposed on the gate insulation layer 112.

The third gate electrode GE3 is disposed on the gate insulation layer 112 to overlap with the third active layer ACT3. The third gate electrode GE3 may be electrically connected to the sensing line SL. The third transistor TR3 may be turned on or off on the basis of the sensing voltage transmitted to the third transistor TR3. The third gate electrode GE3 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Meanwhile, the third gate electrode GE3 may extend from the sensing line SL. That is, the third gate electrode GE3 may be integrated with the sensing line SL. The third gate electrode GE3 and the sensing line SL may be made of the same electrically conductive material. For example, the sensing line SL may be made of copper (Cu), aluminum (Al), molybdenum (Mo), nickel (Ni), titanium (Ti), chromium (Cr), or an alloy thereof. However, the present disclosure is not limited thereto.

The sensing line SL is a line that transmits the sensing voltages to the plurality of subpixels SP and extends in the row direction between the plurality of subpixels SP. For example, the sensing line SL may extend in the row direction at a boundary between the plurality of subpixels SP and intersect the plurality of high-potential power lines VDD, the plurality of data lines DL, and the plurality of reference lines RL that extend in the column direction.

The third source electrode SE3 may be electrically connected to the third active layer ACT3 through the contact hole formed in the gate insulation layer 112. The third source electrode SE3 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Meanwhile, a part of the third active layer ACT3, which is in contact with the third source electrode SE3, may be electrically connected to the light-blocking layer LS through the contact hole formed in the buffer layer 111. That is, the third source electrode SE3 may be electrically connected to the light-blocking layer LS with the third active layer ACT3 interposed therebetween. Therefore, the third source electrode SE3 and the first source electrode SE1 may be electrically connected to each other through the light-blocking layer LS.

The third drain electrode DE3 may be electrically connected to the third active layer ACT3 through the contact hole formed in the gate insulation layer 112. The third drain electrode DE3 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The third drain electrode DE3 may be electrically connected to the reference line RL. For example, the third drain electrodes DE3 of the red subpixel SPR, the white subpixel SPW, the blue subpixel SPB, and the green subpixel SPG, which constitute the single pixel, may be electrically connected to the same reference line RL. That is, the plurality of subpixels SP, which constitutes a single pixel, may share the single reference line RL.

In this case, an auxiliary reference line RLa may be disposed to transmit signals to the plurality of subpixels SP disposed side by side in the row direction through the reference line RL extending in the column direction. The auxiliary reference line RLa may extend in the row direction and electrically connect the reference line RL to the third drain electrode DE3 of each of the plurality of subpixels SP. One end of the auxiliary reference line RLa may be electrically connected to the reference line RL through the contact hole formed in the buffer layer 111 and the gate insulation layer 112. Further, the other end of the auxiliary reference line RLa may be electrically connected to the third drain electrode DE3 of each of the plurality of subpixels SP. In this case, the auxiliary reference line RLa may be integrated with the third drain electrode DE3 of each of the plurality of subpixels SP. The reference voltage may be transmitted from the reference line RL to the third drain electrode DE3 through the auxiliary reference line RLa. However, the auxiliary reference line RLa may be formed separately from the third drain electrode DE3. However, the present disclosure is not limited thereto.

The storage capacitor SC is disposed in the circuit area CA of the plurality of subpixels SP. The storage capacitor SC may store a voltage between the first gate electrode GE1 and the first source electrode SE1 of the first transistor TR1 so that the light-emitting element OLED may continuously maintain the same state during a single frame. The storage capacitor SC includes a first capacitor electrode SC1 and a second capacitor electrode SC2.

The first capacitor electrode SC1 is disposed between the insulation layer IN and the buffer layer 111 in each of the plurality of subpixels SP. The first capacitor electrode SC1 may be disposed to be closest to the substrate 110 among the conductive constituent elements disposed on the substrate 110. The first capacitor electrode SC1 may be integrated with the light-blocking layer LS. The first capacitor electrode SC1 may be electrically connected to the first source electrode SE1 through the light-blocking layer LS.

The buffer layer 111 is disposed on the first capacitor electrode SC1. The second capacitor electrode SC2 is disposed on the buffer layer 111. The second capacitor electrode SC2 may be disposed to overlap with the first capacitor electrode SC1. The second capacitor electrode SC2 may be integrated with the second source electrode SE2 and electrically connected to the second source electrode SE2 or the first gate electrode GE1. For example, the second source electrode SE2 and the second capacitor electrode SC2 may be formed by forming a semiconductor material on the buffer layer 111 and making a part of the semiconductor material conductive. Therefore, a portion of the semiconductor material, which does not become conductive, may serve as the second active layer ACT2. A portion of the semiconductor material, which becomes conductive, may serve as the second source electrode SE2 or the second capacitor electrode SC2. Further, as described above, the first gate electrode GE1 is electrically connected to the second source electrode SE2 through the contact hole formed in the gate insulation layer 112. Therefore, the second capacitor electrode SC2 may be integrated with the second source electrode SE2 and electrically connected to the second source electrode SE2 and the first gate electrode GE1.

In summary, the first capacitor electrode SC1 of the storage capacitor SC may be integrated with the light-blocking layer LS and electrically connected to the light-blocking layer LS, the first source electrode SE1, and the third source electrode SE3. Further, the second capacitor electrode SC2 may be integrated with the second source electrode SE2 or the second active layer ACT2 and electrically connected to the second source electrode SE2 and the first gate electrode GE1. Therefore, the first capacitor electrode SC1 and the second capacitor electrode SC2, which overlap with each other with the buffer layer 111 interposed therebetween, may maintain the light-emitting element OLED in the constant state by constantly maintaining the voltages of the first gate electrode GE1 and the first source electrode SE1 of the first transistor TR1 while the light-emitting element OLED emits light.

The passivation layer 113 is disposed on the first transistor TR1, the second transistor TR2, the third transistor TR3, and the storage capacitor SC. The passivation layer 113 is an insulation layer for protecting the components disposed on a lower portion of the passivation layer 113. For example, the passivation layer 113 may be configured as a single layer or multilayer made of silicon oxide (SiOx) or silicon nitride (SiNx). However, the present disclosure is not limited thereto. In addition, the passivation layer 113 may be excluded in accordance with the exemplary aspects.

The plurality of color filters CF is disposed in the light-emitting area EA of each of the plurality of subpixels SP and provided on the passivation layer 113. As described above, the display device 100 according to the exemplary aspect of the present disclosure is the bottom-emission type display device that allows the light emitted from the light-emitting element OLED to propagate to the lower sides of the light-emitting element OLED and the substrate 110. Therefore, the plurality of color filters CF may be disposed below the light-emitting element OLED. The light emitted from the light-emitting element OLED may be implemented in the form of light beams with various colors by passing through the plurality of color filters CF.

The plurality of color filters CF includes the red color filter CFR, a blue color filter CFB, and the green color filter CFG. The red color filter CFR may be disposed in the light-emitting area of the red subpixel SPR among the plurality of subpixels SP. The blue color filter CFB may be disposed in the light-emitting area of the blue subpixel SPB. The green color filter CFG may be disposed in the light-emitting area of the green subpixel SPG.

The overcoating layer 114 is disposed on the passivation layer 113 and the plurality of color filters CF. The overcoating layer 114 is an insulation layer for flattening an upper portion of the substrate 110 on which the first transistor TR1, the second transistor TR2, the third transistor TR3, the storage capacitor SC, the plurality of high-potential power lines VDD, the plurality of data lines DL, the plurality of reference lines RL, the plurality of gate lines GL, and the plurality of sensing lines SL are disposed. The overcoating layer 114 may be configured as a single layer or multilayer made of an organic material, for example, polyimide or poly acrylic. However, the present disclosure is not limited thereto.

The light-emitting element OLED is disposed in the light-emitting area of each of the plurality of subpixels SP. The light-emitting element OLED is disposed on the overcoating layer 114 of each of the plurality of subpixels SP. The light-emitting element OLED includes the anode 121, a light-emitting layer 122, and a cathode 123.

The anode 121 is disposed on the overcoating layer 114 in the light-emitting area EA. Because the anode 121 supplies holes to the light-emitting layer EL, the anode 121 may be made of an electrically conductive material having a high work function. For example, the anode 121 may be made of a transparent electrically conductive material such as indium tin oxide (ITO) or indium zinc oxide (IZO), but the present disclosure is not limited thereto.

Meanwhile, the anode 121 may extend toward the circuit area CA. A part of the anode 121 may extend from the light-emitting area EA toward the first source electrode SE1 in the circuit area CA and be electrically connected to the first source electrode SE1 through the contact hole formed in the overcoating layer 114 and the passivation layer 113. Therefore, the anode 121 of the light-emitting element OLED may extend to the circuit area CA and be electrically connected to the first source electrode SE1 of the first transistor TR1 or the second capacitor electrode SC2 of the storage capacitor SC.

The light-emitting layer 122 is disposed on the anode 121 in the light-emitting area EA and the circuit area CA. The light-emitting layer 122 may be configured as a single layer over the plurality of subpixels SP. That is, the light-emitting layers 122 of the plurality of subpixels SP may be connected to and integrated with one another. The light-emitting layer 122 may be configured as a single light-emitting layer. The light-emitting layer 122 may have a structure in which a plurality of light-emitting layers configured to emit light beams with different colors is stacked. The light-emitting layer 122 may further include organic layers such as a hole injection layer, a hole transport layer, an electron transport layer, and an electron injection layer.

The cathode 123 is disposed on the light-emitting layer 122 in the light-emitting area EA and the circuit area CA. Because the cathode 123 supplies electrons to the light-emitting layer 122, the cathode 123 may be made of an electrically conductive material having a low work function. The cathode 123 may be configured as a single layer over the plurality of subpixels SP. That is, the cathodes 123 of the plurality of subpixels SP may be connected to and integrated with one another. For example, the cathode 123 may be made of transparent conductive material such as indium tin oxide (ITO) or indium zinc oxide (IZO) or made of an alloy of ytterbium (Yb). The cathode 123 may further include a metal doping layer. However, the present disclosure is not limited thereto. Meanwhile, although not illustrated in FIGS. 4 and 5, the cathode 123 of the light-emitting element OLED may be electrically connected to the low-potential power line VSS and receive the low-potential power voltage.

The bank 115 is disposed between the anode 121 and the light-emitting layer 122. The bank 115 is disposed to overlap with the display area AA and cover an edge of the anode 121. The bank 115 may be disposed at a boundary between the adjacent subpixels SP and reduce mixing of colors of the light beams emitted from the light-emitting element OLED of each of the plurality of subpixels SP. The bank 115 may be made of an insulating material. For example, the bank 115 may be made of polyimide-based resin, acryl-based resin, or benzocyclobutene (BCB)-based resin. However, the present disclosure is not limited thereto.

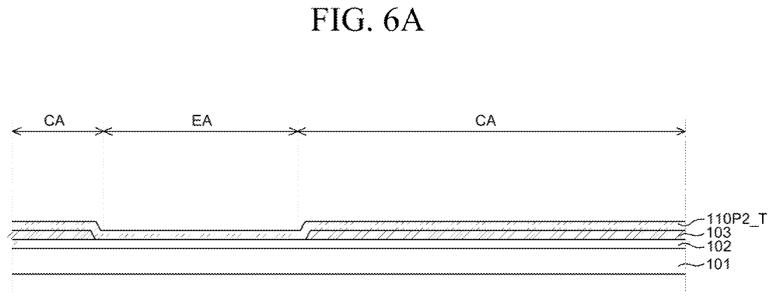

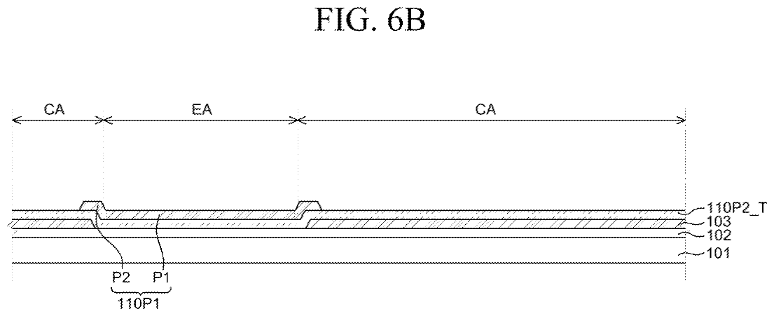

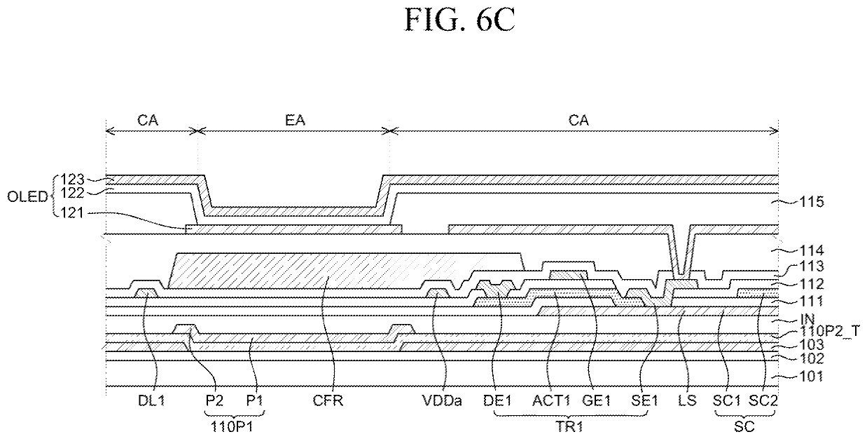

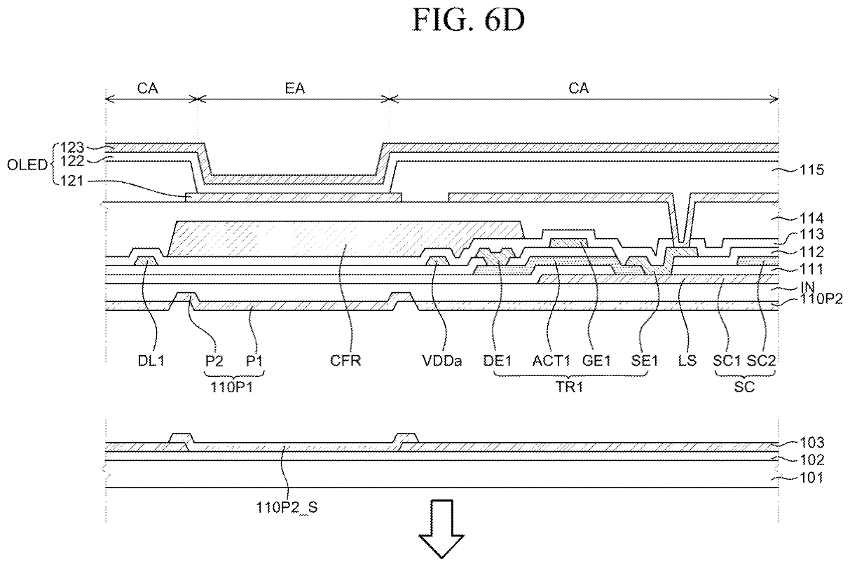

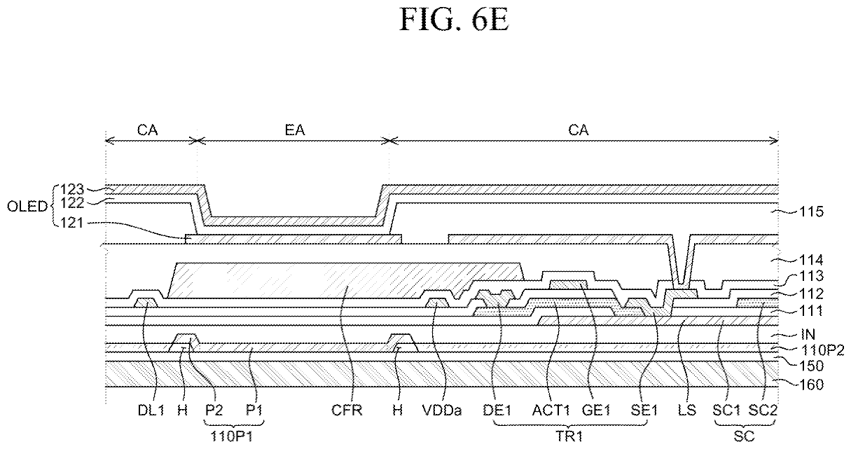

Hereinafter, a method of manufacturing the display device 100 according to the exemplary aspect of the present disclosure will be described with reference to FIGS. 6A to 6E.

FIGS. 6A to 6E are cross-sectional views schematically illustrating a method of manufacturing the display device according to the exemplary aspect of the present disclosure.

First, with reference to FIG. 6A, a temporary insulation layer 102 is formed on an upper portion of a temporary substrate 101. The temporary insulation layer 102 may be made of an inorganic material, for example, silicon oxide (SiOx) or silicon nitride (SiNx).

Next, a temporary layer 103 is formed on the upper portion of the temporary substrate 101 on which the temporary insulation layer 102 is formed. In this case, the temporary layer 103 may be made of the same material as the plurality of first substrate patterns 110P1 of the substrate 110. For example, the temporary layer 103 may be made of a transparent conducting oxide material, for example, any one of indium tin oxide (ITO), indium zinc oxide (IZO), and indium tin zinc oxide (ITZO). Alternatively, the temporary layer 103 may be made of a transparent oxide semiconductor such as indium-gallium-zinc oxide (IGZO), indium gallium oxide (IGO), and indium-tin-zinc oxide (ITZO).

Next, a temporary second substrate pattern 110P2_T is formed on an upper portion of the temporary substrate 101 on which the temporary layer 103 is formed. The temporary second substrate pattern 110P2_T may be disposed in both the light-emitting area EA and the circuit area CA. The temporary second substrate pattern 110P2_T may be made of a material used as a sacrificial layer during the LLO process. For example, the temporary second substrate pattern 110P2_T may include a silicon-based material such as hydrogenated amorphous silicon or amorphous silicon hydrogenated and doped with impurities. However, the present disclosure is not limited thereto.

Next, with reference to FIG. 6B, the first substrate pattern 110P1 corresponding in shape to the light-emitting area EA is formed. More specifically, the first substrate pattern 110P1 may be formed to include the first pattern P1 disposed in the flat area, and the second pattern P2 connected to the end of the first pattern P1 and protruding from an upper portion of the temporary second substrate pattern 110P2_T. In this case, the second pattern P2 formed on the upper portion of the temporary second substrate pattern 110P2_T may be disposed to overlap with the temporary layer 103 and have the inclined shape.

Next, with reference to FIG. 6C, after the first substrate pattern 110P1 is formed, a process of sequentially forming the constituent elements on the upper portion of the first substrate pattern 110P1 and the upper portion of the temporary second substrate pattern 110P2_T in a direction from the insulation layer IN is performed.

Next, with reference to FIG. 6D, the LLO process is performed to separate a second substrate pattern sacrificial layer 110P2_S, which corresponds to the temporary substrate 101, the temporary insulation layer 102, the temporary layer 103, and the light-emitting area EA, from the first substrate pattern 110P1 and the second substrate pattern 110P2. During the LLO process, the second substrate pattern sacrificial layer 110P2_S and the temporary layer 103 are detached by a laser from the substrate 110 including the first substrate pattern 110P1 and the second substrate pattern 110P2. Therefore, the temporary substrate 101, the temporary insulation layer 102, the temporary layer 103, and the second substrate pattern sacrificial layer 110P2_S may be detached in the arrow direction illustrated in FIG. 6D.

More specifically, as described above, the second substrate pattern 110P2 may be made of hydrogenated amorphous silicon or amorphous silicon hydrogenated and doped with impurities. When the lower portion of the temporary substrate 101 is irradiated with laser beams, the temporary second substrate pattern 110P2_T is dehydrogenated, such that the second substrate pattern sacrificial layer 110P2_S, the temporary layer 103, the temporary insulation layer 102, and the temporary substrate 101 may be separated from the substrate 110. In this case, the transparent conducting oxide material or the oxide semiconductor material, which constitutes the first substrate pattern 110P1 and the temporary layer 103, is a material that may be subjected to the LLO process together with the second substrate pattern sacrificial layer 110P2_S and the temporary second substrate pattern 110P2_T. Therefore, it is possible to easily separate the substrate 110 and the temporary substrate 101 even though the first substrate pattern 110P1 is formed on the substrate 110 corresponding to the light-emitting area EA of the subpixel SP and the second substrate pattern 110P2 is formed on the substrate 110 corresponding to the circuit area CA of the subpixel SP. In this case, the second substrate pattern sacrificial layer 110P2_S may be separated from the substrate 110 to have the same shape as the first substrate pattern 110P1.

Next, with reference to FIG. 6E, the polarizing plate 160 or the barrier film may be disposed, by the bonding layer 150, on the bottom surface of the substrate 110 including the first substrate pattern 110P1 and the second substrate pattern 110P2. The polarizing plate 160 suppresses the reflection of external light. The barrier film suppresses the penetration of foreign materials. Therefore, the gap H may be formed between the first pattern P1 of the first substrate pattern 110P1 and the second substrate pattern 110P2.

In the display device 100 according to the exemplary aspect of the present disclosure, the first substrate pattern 110P1 of the substrate 110 is made of any one of a transparent conducting oxide and an oxide semiconductor, such that the display device 100 may decrease in thickness. In the related art, a plastic substrate is mainly used for a substrate of a display device. However, because the plastic substrate is formed by applying and curing a substrate material at a high temperature, there is a problem in that a large amount of time is required, and it is difficult to reduce a thickness to a predetermined level or less. In contrast, the transparent conducting oxide and the oxide semiconductor may allow the display device to have a very small thickness through a deposition process such as sputtering. Therefore, in the display device 100 according to the exemplary aspect of the present disclosure, the first substrate pattern 110P1 of the substrate 110 for supporting several components of the display device 100 is made of the transparent conducting oxide layer or oxide semiconductor layer. Therefore, it is possible to reduce a thickness of the display device 100 and implement slim design.

In the display device 100 according to the exemplary aspect of the present disclosure, the first substrate pattern 110P1 of the substrate 110 is made of the transparent conducting oxide or oxide semiconductor, such that it is possible to improve the flexibility of the display device 100 or reduce stress caused by the deformation of the display device 100. Specifically, when the substrate 110 is made of the transparent conducting oxide layer or oxide semiconductor, the first substrate pattern 110P1 of the substrate 110 may be formed to have a very thin film. In this case, the first substrate pattern 110P1 of the substrate 110 may be referred to as a first transparent thin-film layer. Therefore, the display device 100 including the substrate 110 may have high flexibility. Therefore, the display device 100 may be easily curved or rolled up. Therefore, in the display device 100 according to the exemplary aspect of the present disclosure, the first substrate pattern 110P1 of the substrate 110 is made of any one of the transparent conducting oxide layer and the oxide semiconductor layer, such that it is possible to improve flexibility of the display device 100 and reduce stress caused by the deformation of the display device 100. Therefore, it is possible to minimize cracks formed in the display device 100.

In addition, in the display device 100 according to the exemplary aspect of the present disclosure, the first substrate pattern 110P1 of the substrate 110 may be made of any one of the transparent conducting oxide layer and the oxide semiconductor layer, thereby reducing the likelihood that the static electricity occurs on the substrate 110. If the substrate 110 is made of plastic and the static electricity occurs, various types of lines and driving elements on the substrate 110 may be damaged by the static electricity, or the static electricity may affect the operations of the lines and components, which may deteriorate the display quality. Instead, the first substrate pattern 110P1 of the substrate 110 is made of the transparent conducting oxide layer or oxide semiconductor layer, it is possible to minimize the static electricity occurring on the substrate 110 and simplify the configuration for blocking and discharging the static electricity. Therefore, in the display device 100 according to the exemplary aspect of the present disclosure, the first substrate pattern 110P1 of the substrate 110 is made of any one of the transparent conducting oxide layer or oxide semiconductor layer that is low in the likelihood of the occurrence of the static electricity. Therefore, it is possible to minimize damage or deterioration in display quality caused by the static electricity.

In addition, in the display device 100 according to the exemplary aspect of the present disclosure, the first substrate pattern 110P1 of the substrate 110 is made of one of the transparent conducting oxide and the oxide semiconductor. Therefore, it is possible to minimize the penetration of outside moisture or oxygen into the display device 100 through the substrate 110. When the first substrate pattern 110P1 of the substrate 110 is made of a transparent conducting oxide layer or an oxide semiconductor, the substrate 110 is formed in a vacuum environment, such that the likelihood of the occurrence of particles is remarkably low. In addition, sizes of the particles are very small even though the particles occur. Therefore, it is possible to minimize the penetration of moisture and oxygen into the display device 100. Therefore, in the display device 100 according to the exemplary aspect of the present disclosure, the first substrate pattern 110P1 of the substrate 110 is made of the transparent conducting oxide or oxide semiconductor that decreases the likelihood of the occurrence of particles and is excellent in moisture transmission performance. Therefore, it is possible to improve reliability of the display device 100 and the light-emitting element OLED including the organic layer.

Various types of elements, such as the plurality of lines and the transistors, are disposed on the substrate. Further, when voltages are applied to various types of elements, electric currents flow, and various electric fields may be formed by the influence of the electric currents. In this case, the substrate, which is made of a transparent conducting oxide or oxide semiconductor layer, is affected by various electric fields, such that electrons may be collected on a part of the substrate, and positive holes may be collected on another part of the substrate. Therefore, the polarization, i.e., another electric field may be created. Further, the electric fields formed on the substrate may affect properties of various components disposed on the substrate.

Therefore, in the display device 100 according to the exemplary aspect of the present disclosure, the substrate 110 is configured such that the plurality of first substrate patterns 110P1, which overlaps with the light-emitting areas EA of the subpixel SP, is each made of a transparent conducting oxide or an oxide semiconductor, and the second substrate pattern 110P2, which overlaps with the circuit area CA of the subpixel SP, is made of a silicon-based material. Therefore, it is possible to minimize parasitic capacitance formed between the substrate and the plurality of thin-film transistors TR1, TR2, and TR3, the storage capacitor, and various lines.

In the display device 100 according to the exemplary aspect of the present disclosure, the ends of the plurality of first substrate patterns 110P1 of the substrate 110, which overlaps with the light-emitting areas EA of the subpixel SP, protrude in the direction of the insulation layer IN and include the inclined shapes. Therefore, it is possible to increase the transmittance of the display device 100. The transmittance increases when light enters a front surface of the first substrate patterns 110P1. As an incident angle increases, the transmittance decreases, and the reflectance increases. In the display device 100 according to the exemplary aspect of the present disclosure, the first substrate pattern 110P1 is disposed inclinedly on the boundary of the light-emitting area EA. Therefore, the light, which is emitted from the light-emitting element OLED and may be reflected and trapped in the display device 100 if the light enters a flat surface, may normally passes through the first substrate pattern 110P1 without being reflected by the inclined portion of the first substrate pattern 110P1. Therefore, in the display device 100 according to the exemplary aspect of the present disclosure, the transmittance of the light emitted from the light-emitting element OLED may increase.

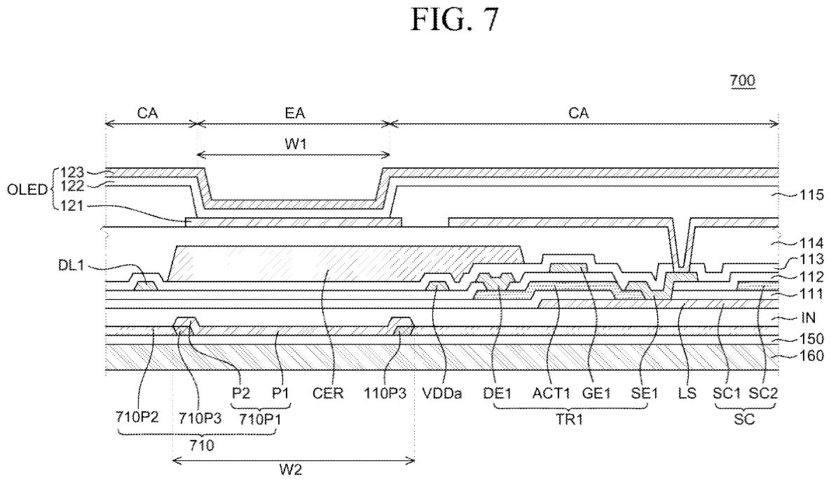

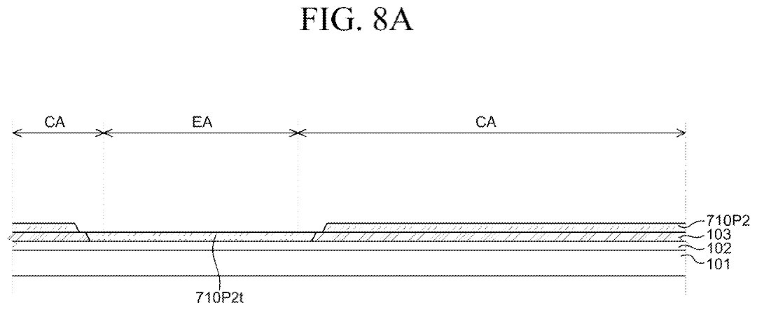

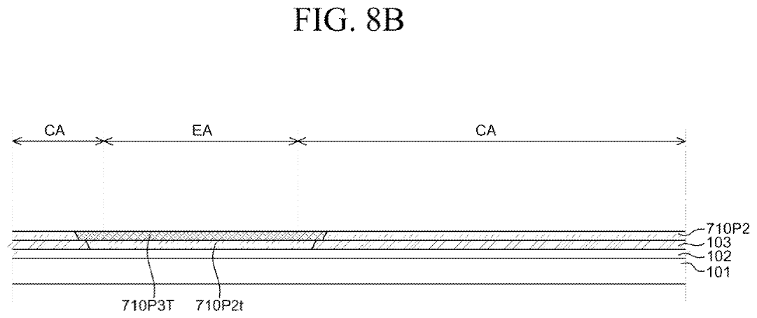

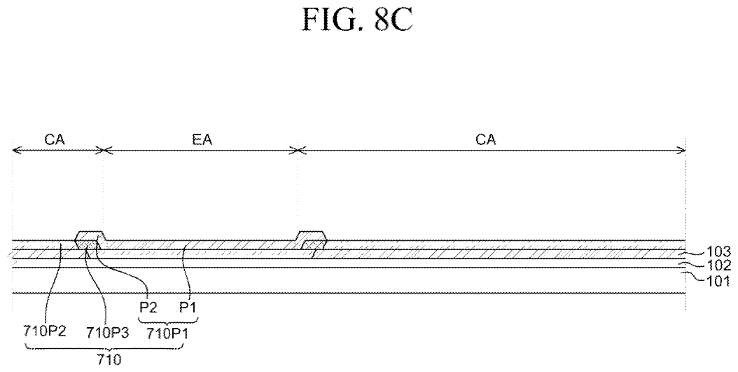

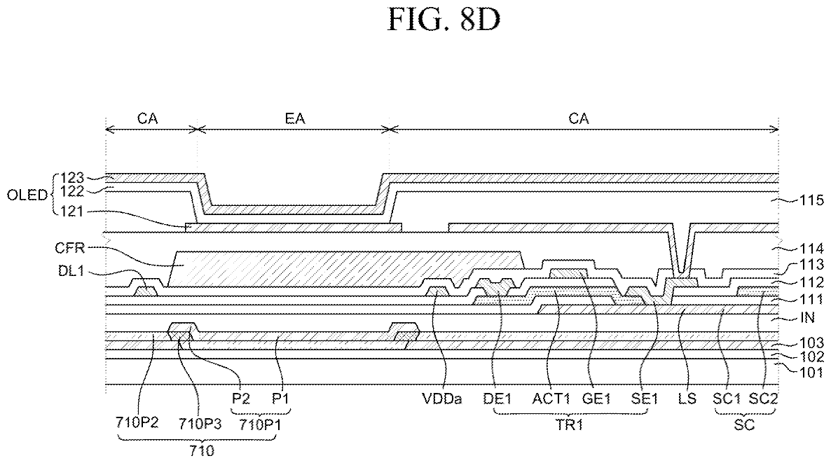

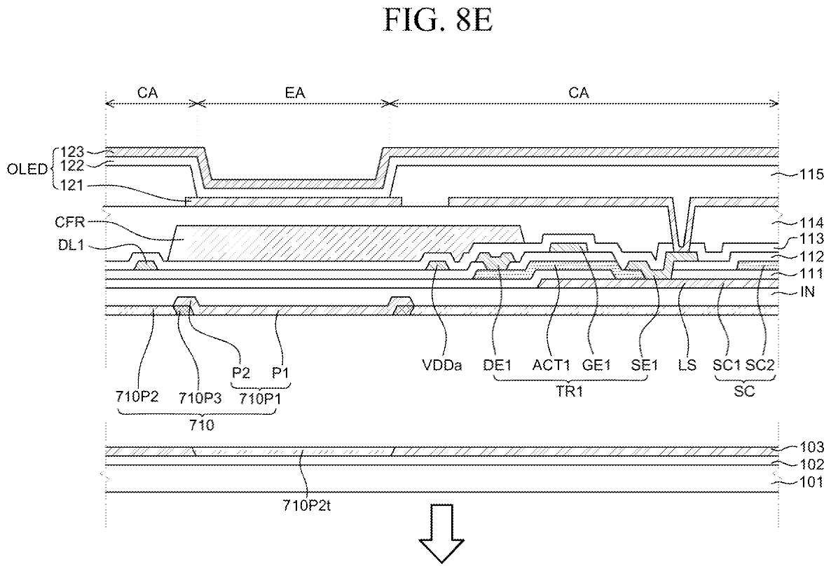

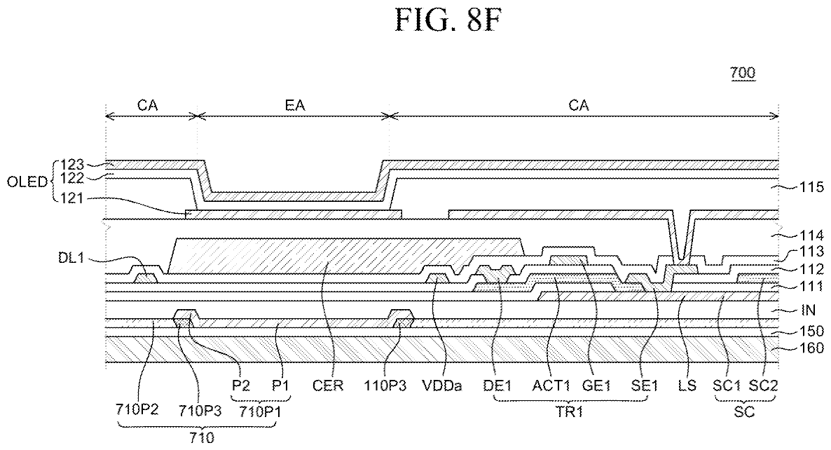

FIG. 7 is a cross-sectional view of a display device according to another exemplary aspect of the present disclosure. FIGS. 8A to 8F are cross-sectional views schematically illustrating a method of manufacturing the display device according to another exemplary aspect of the present disclosure. A display device 700 in FIGS. 7 to 8F is substantially identical in configuration to the display device 100 illustrated in FIGS. 1 to 6E, except for a substrate 710. Therefore, repeated descriptions of the identical components will be omitted.

First, with reference to FIG. 7, the substrate 710 may include a first substrate pattern 710P1 formed to correspond to the light-emitting area EA, a second substrate pattern 710P2 formed to correspond to the circuit area CA, and a third substrate pattern 710P3 formed between the first substrate pattern 710P1 and the second substrate pattern 710P2.

The first substrate pattern 710P1 may include a first pattern P1 configured to overlap with the light-emitting area EA, and a second pattern P2 configured to overlap with a part of the light-emitting area EA and a part of the circuit area CA. The second pattern P2 may be disposed on an upper portion of the second substrate pattern 710P2 and/or an upper portion of the third substrate pattern 710P3. The first pattern P1 and the second pattern P2 may be integrated. The second pattern P2 may have an inclined shape and be referred to as a protruding pattern. As described above, the first substrate pattern 710P1 including the first and second patterns P1 and P2 may be made of a transparent conducting oxide material or an oxide semiconductor material. The first and second patterns P1 and P2 of the first substrate pattern 710P1 may be substantially identical to the first and second patterns P1 and P2 of the first substrate pattern 110P1 described with reference to FIGS. 1 to 6E.

The second substrate pattern 710P2 may be disposed in an area that overlaps with the circuit area CA. A side surface of the second substrate pattern 710P2 may adjoin the third substrate pattern 710P3, and an upper portion of the second substrate pattern 710P2 may adjoin the first substrate pattern 710P1 and an insulation film IN. The second substrate pattern 710P2 may be made of the same material as a sacrificial layer used for an LLO process. For example, the second substrate pattern 710P2 may be made of a silicon-based material such as hydrogenated amorphous silicon. However, the present disclosure is not limited thereto.

The third substrate pattern 710P3 may be disposed in the area of the substrate 710 that overlaps with the circuit area CA. The third substrate pattern 710P3 may be disposed between the first substrate pattern 710P1 and the second substrate pattern 710P2. That is, the third substrate pattern 710P3 may be disposed in an area surrounded by the first substrate pattern 710P1, the second substrate pattern 710P2, and the bonding layer 150 disposed on the lower portion of the substrate 710. The third substrate pattern 710P3 may be made of the same material as the overcoating layer 114. For example, the third substrate pattern 710P3 may be made of one or more of polyimide and poly acrylic. In addition, the third substrate pattern 710P3 may be made of a flexible material, for example, one or more of polyimide and urethane. However, the present disclosure is not limited thereto.

A method of manufacturing the display device 700 according to another exemplary aspect of the present disclosure will be described. First, with reference to FIG. 8A, the temporary layer 103 is disposed on the upper portion of the temporary substrate 101 having the entire surface on which the temporary insulation layer 102 is disposed.

Thereafter, a temporary second substrate pattern material is applied onto an upper portion of the temporary substrate 101 and an upper portion of the temporary layer 103, and then the temporary second substrate pattern material is patterned. Therefore, a sub-pattern 710P2t having the temporary second substrate pattern is disposed between the temporary layers 103, and the second substrate pattern 710P2 is disposed on the temporary layer 103.

Next, with reference to FIG. 8B, a temporary third substrate pattern 710P3T is formed on the sub-pattern 710P2t having the temporary second substrate pattern.

Next, with reference to FIG. 8C, the third substrate pattern 710P3 is formed by etching the temporary third substrate pattern 710P3T.

Thereafter, the first substrate pattern 710P1 having an inclined shape is formed to correspond to an area from which the third substrate pattern 710P3 and the temporary third substrate pattern 710P3T are etched and removed.

Next, with reference to FIG. 8D, after the first substrate pattern 710P1 is formed, a process of sequentially forming the constituent elements on the upper portion of the first substrate pattern 710P1 and the upper portion of the second substrate pattern 710P2 in the direction from the insulation layer IN is performed.

Next, with reference to FIG. 8E, the LLO process is performed to separate the sub-pattern 710P2t having the temporary second substrate pattern, which corresponds to the temporary substrate 101, the temporary insulation layer 102, the temporary layer 103, and the light-emitting area EA, from the substrate 710 including the first substrate pattern 710P1, the second substrate pattern 710P2, and the third substrate pattern 710P3. During the LLO process, the temporary layer 103 and the sub-pattern 710P2t having the temporary second substrate pattern are separated by a laser from the substrate 710 including the first substrate pattern 710P1, the second substrate pattern 710P2, and the third substrate pattern 710P3. Therefore, the temporary substrate 101, the temporary insulation layer 102, the temporary layer 103, and the sub-pattern 710P2t having the temporary second substrate pattern may be detached in the arrow direction illustrated in FIG. 8E.

Next, with reference to FIG. 8F, the polarizing plate 160 or the barrier film may be disposed, by the bonding layer 150, on the bottom surface of the substrate 710 including the first substrate pattern 710P1, the second substrate pattern 710P2, and the third substrate pattern 710P3. The polarizing plate 160 suppresses the reflection of external light. The barrier film suppresses the penetration of foreign materials.

In the display device 700 according to another exemplary aspect of the present disclosure, the substrate 710 is configured such that the plurality of first substrate patterns 710P1, which overlaps with the light-emitting areas EA of the subpixel SP, is each made of a transparent conducting oxide or an oxide semiconductor, and the second substrate pattern 710P2, which overlaps with the circuit area CA of the subpixel SP, is made of a silicon-based material. Therefore, it is possible to minimize parasitic capacitance formed between the substrate and the plurality of thin-film transistors TR1, TR2, and TR3, the storage capacitor, and various lines.

In the display device 700 according to another exemplary aspect of the present disclosure, the ends of the plurality of first substrate patterns 710P1 of the substrate 710, which overlaps with the light-emitting areas EA of the subpixel SP, protrude in the direction of the insulation layer IN and include the inclined shapes. Therefore, it is possible to increase the transmittance of the display device 700. The transmittance increases when light enters a front surface of the first substrate patterns 110P1. As an incident angle increases, the transmittance decreases, and the reflectance increases. In the display device 700 according to another exemplary aspect of the present disclosure, the first substrate pattern 710P1 is disposed inclinedly on the boundary of the light-emitting area EA. Therefore, the light, which is emitted from the light-emitting element OLED and may be reflected and trapped in the display device 700 if the light enters a flat surface, may normally passes through the first substrate pattern 710P1 without being reflected by the inclined portion of the first substrate pattern 710P1. Therefore, in the display device 700 according to another exemplary aspect of the present disclosure, the transmittance of the light emitted from the light-emitting element OLED may increase.

In the display device 700 according to another exemplary aspect of the present disclosure, the third substrate pattern 710P3, which is made of a material having flexibility or bondability, may be formed between the first substrate pattern 710P1 and the second substrate pattern 710P2, thereby suppressing the occurrence of cracks in the constituent elements of the display device 700. That is, it is possible to suppress the occurrence of cracks in the display device 700 that may be caused when an empty space is present between the first substrate pattern 710P1 and the second substrate pattern 710P2.

The exemplary aspects of the present disclosure may also be described as follows:

According to an aspect of the present disclosure, a display device includes a substrate comprising a display area including a plurality of subpixels, and a non-display area, a film member disposed on a lower portion of the substrate, a bonding layer disposed between the film member and the substrate and an insulation layer disposed on the substrate, wherein the plurality of subpixels each comprises a light-emitting area in which a light-emitting element is disposed, and a circuit area in which a drive circuit for operating the light-emitting element is disposed, wherein the substrate comprises a plurality of first substrate patterns disposed to correspond to the light-emitting area, and a second substrate pattern disposed to correspond to the circuit area, and wherein the plurality of first substrate patterns and the second substrate pattern are made of different materials.

A width of each of the plurality of first substrate patterns may be equal to or larger than a width of the light-emitting area.

The plurality of first substrate patterns may include a first pattern configured to overlap with the light-emitting area and a second pattern integrated with the first pattern and disposed at a portion adjacent to the second substrate pattern, and wherein at least a part of the second pattern may overlap with the circuit area.

The second pattern may have an inclined portion, and an end of the light-emitting area may overlap with the first pattern or the inclined portion of the second pattern.

The plurality of first substrate patterns may be made of a transparent conductive material or an oxide semiconductor material, and the second substrate pattern may be made of a silicon-based material.

A gap may be disposed between the plurality of first substrate patterns and the second substrate pattern.

The display device may further include a third substrate pattern disposed in the gap and made of any one of poly acrylic, polyimide, and urethane.

The gap may be disposed at a position surrounded by the plurality of first substrate patterns, the second substrate pattern, and the bonding layer.

The insulation layer may include an inorganic insulation layer disposed on the plurality of first substrate patterns and the second substrate pattern.

The film member may include at least one of a polarizing plate and a barrier film.

According to another aspect of the present disclosure, a display device includes a substrate comprising a light-emitting area, and a circuit area in which a drive circuit for operating a light-emitting element is disposed, the light-emitting element provided on the substrate and disposed in the light-emitting area and an insulation layer disposed on the substrate, wherein the substrate includes a plurality of first substrate patterns configured to overlap with a part of the light-emitting area and a part of the circuit area, a second substrate pattern configured to overlap with the circuit area and made of a material different from a material of the plurality of first substrate patterns and a plurality of third substrate patterns configured to overlap with the circuit area and disposed between the plurality of first substrate patterns and the second substrate pattern, the plurality of third substrate patterns made of a material different from a material of the plurality of first substrate patterns and a material of the second substrate pattern.

The plurality of first substrate patterns each may include protruding patterns provided at two opposite ends thereof, and the protruding patterns may be disposed on at least one of the second substrate pattern and the plurality of third substrate patterns.

One side surface and a top surface of each of the plurality of third substrate patterns adjoin the plurality of first substrate patterns, and the plurality of first substrate patterns each may have an inclined shape.

The plurality of first substrate patterns may be each made of a transparent conducting oxide material or an oxide semiconductor material, the second substrate pattern may be made of an amorphous silicon material, and the plurality of third substrate patterns may be each made of any one of polyacrylic, polyimide, and urethane.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate including a plurality of subpixels,
wherein the plurality of subpixels each comprises a light-emitting area in which a light-emitting element is disposed, and a circuit area in which a drive circuit for operating the light-emitting element is disposed,
wherein the substrate comprises a plurality of first substrate patterns disposed to correspond to the light-emitting area, and a second substrate pattern disposed to correspond to the circuit area, and
wherein the plurality of first substrate patterns are made of different materials from the second substrate pattern.

2. The display device of claim 1, wherein a width of each of the plurality of first substrate patterns is equal to or larger than a width of the light-emitting area.

3. The display device of claim 2, wherein the plurality of first substrate patterns comprises:
a first pattern overlapping with the light-emitting area; and
a second pattern connected with the first pattern and disposed at a portion adjacent to the second substrate pattern, and
wherein at least a part of the second pattern overlaps with the circuit area.

4. The display device of claim 3, wherein the second pattern has an inclined portion, and an edge of the light-emitting area overlap with the first pattern or the inclined portion of the second pattern.

5. The display device of claim 1, wherein the plurality of first substrate patterns is made of a transparent conducting oxide material or an oxide semiconductor material, and the second substrate pattern is made of a silicon-based material.

6. The display device of claim 5, wherein the transparent conductive material is one or more indium tin oxide, indium zinc oxide and indium tin zinc oxide,
wherein the oxide semiconductor material is one or more of indium-gallium-zinc oxide, indium gallium oxide and indium-tin-zinc oxide, and
wherein the silicon-based material is one or more of hydrogenated amorphous silicon and amorphous silicon hydrogenated and doped with impurities.

7. The display device of claim 1, wherein a gap is disposed between the plurality of first substrate patterns and the second substrate pattern.

8. The display device of claim 7, further comprising a third substrate pattern disposed in the gap and made of one of poly acrylic, polyimide, and urethane.

9. The display device of claim 7, further comprising:
a film member under the substrate; and
a bonding layer between the film member and the substrate, and
wherein the gap is disposed at a position surrounded by the plurality of first substrate patterns, the second substrate pattern, and the bonding layer.

10. The display device of claim 1, furthering comprising an insulation layer above the substrate.

11. The display device of claim 10, wherein the insulation layer comprises inorganic material and is disposed on the plurality of first substrate patterns and the second substrate pattern.

12. The display device of claim 1, further comprising a film member under the substrate.

13. The display device of claim 12, wherein the film member comprises at least one of a polarizing plate and a barrier film.

14. The display device of claim 1, wherein the second substrate pattern surrounds the plurality of first substrate patterns.

15. A display device comprising:
a substrate comprising a light-emitting area, and a circuit area in which a drive circuit for operating a light-emitting element is disposed,
wherein the substrate comprises:
a plurality of first substrate patterns overlapping with a part of the light-emitting area and a part of the circuit area;
a second substrate pattern overlapping with the circuit area and made of a material different from a material of the plurality of first substrate patterns.

16. The display device of claim 15, further comprising a plurality of third substrate patterns overlapping with the circuit area and disposed between the plurality of first substrate patterns and the second substrate pattern,
wherein the plurality of third substrate patterns are made of a material different from a material of the plurality of first substrate patterns and a material of the second substrate pattern.

17. The display device of claim 16, wherein the plurality of first substrate patterns each comprises protruding patterns provided at two opposite ends thereof, and the protruding patterns are disposed on at least one of the second substrate pattern and the plurality of third substrate patterns.

18. The display device of claim 17, wherein one side surface and a top surface of each of the plurality of third substrate patterns adjoin the plurality of first substrate patterns, and the plurality of first substrate patterns each has an inclined shape.

19. The display device of claim 18, wherein the plurality of first substrate patterns is each made of a transparent conducting oxide material or an oxide semiconductor material,
wherein the second substrate pattern is made of an amorphous silicon material, and the plurality of third substrate patterns is each made of one or more of polyacrylic, polyimide, and urethane.

20. The display device of claim 15, further comprising an insulation layer over the substrate.
